(19) United States
(12) Patent Application Publication
(10) Pub. No.: US 2009/0278170 A1
(43) Pub. Date: Nov. 12, 2009

(54) SEMICONDUCTOR DEVICE AND MANUFACTURING METHOD THEREOF

(76) Inventors: Yun-Chi Yang, Hsinchu County (TW); Jih-Shun Chiang, Hsinchu City (TW); Cheng-Li Lin, Taoyuan County (TW); Ju-Ping Chen, Hsinchu City (TW); Kuan-Cheng Su, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/116,231

(22) Filed: May 7, 2008

(51) Int. Cl. H01L 29/778; H01L 21/336

(52) U.S. Cl. 257/190; 438/300; 257/344; 257/E29.246; 257/E21.403

(57) ABSTRACT

A method for manufacturing a semiconductor device includes providing a substrate having at least a gate structure formed thereon, forming LDDs in the substrate respectively at two side of the gate structure and a spacer at sidewalls of the gate structure, forming a source/drain in the substrate at two side of the gate structure, performing ant etching process to form recesses respectively in the source/drain, forming a barrier layer in the recesses; and performing a salicide process.

### BACKGROUND OF THE INVENTION

1. Field of the Invention

The present invention relates to a semiconductor device and manufacturing method thereof, and more particularly, to a semiconductor device and manufacturing method capable of replacing pre-amorphous implantation (PAI).

2. Description of the Prior Art

In accordance with the recent trend toward small-sized, lightweight, and slim electronic devices, semiconductor devices are scaled to smaller and smaller dimensions. However, downsizing of the devices results in reduced effective channel regions that causes a well-known undesirable effect: short channel effect (SCE). To suppress SCE, shallower and sharper junctions are needed in transistors. Nevertheless, it is getting more and more difficult to obtain junctions that satisfy certain requirement by performing conventional ion implantation and rapid thermal annealing (RTA) as the devices are scaled down.

Therefore various methodologies are proposed to obtain shallow junction while maximizing dopant activation in processes that are consistent with current manufacturing techniques. For example, pre-amorphization implantation (PAI) is introduced to form an amorphous layer for controlling junction depth precisely and lowering laser beam energy, which may cause undesirable integration problems. In addition, it has been confirmed that an amorphous layer formed by Indium PAI prevents sheet resistance from being rapidly increased with decreasing line width, so-called narrow line width effect, which is caused by agglomeration occurring in self-aligned metal silicide (salicide) processes as the devices are scaled down.

However, it is observed that considerable interstitial defects are created by PAI because the implanting ion causes damage to the silicon lattice of the substrate. The interstitial defects become diffusion paths for dopants, thus diffusion of the dopants are greatly enhanced and transient enhanced diffusion (TED) effect is caused in following annealing processes. TED effect not only deepens the junction profile, but also makes the distribution of the dopant not sheer in a lateral direction, and ironically resulting in severe SCE.

Accordingly, it has become a dilemmatic problem in the conventional method for manufacturing a semiconductor device: in order to reduce SCE and narrow line width effect, PAI is introduced; but PAI itself causes significant TED effect that results in severe SCE and adversely affects reliability of the devices.

### SUMMARY OF THE INVENTION

It is therefore a primary objective of the claimed invention to provide a semiconductor device and manufacturing method thereof that are capable of simultaneously reducing SCE and TED effect.

According to the claimed invention, a method for manufacturing a semiconductor device is provided. The method comprises steps of providing a substrate having at least a gate structure formed thereon; forming lightly doped drains (LDDs) in the substrate respectively at two sides of the gate structure and a spacer at sidewalls of the gate structure; forming a source/drain in the substrate at two sides of the gate structure; performing an etching process to form recesses respectively in the source/drain; forming a barrier layer filling in the recesses; and performing a self-alignment silicide (salicide) process.

According to the claimed invention, a semiconductor device is provided. The semiconductor comprises a gate structure formed on a substrate, lightly doped drains formed in the substrate respectively at two sides of the gate structure, a spacer formed at sidewalls of the gate structure, and a source/drain having a bottom non-amorphous layer and a top amorphous layer in the substrate respectively at two sides of the gate structure.

According to the claimed invention, another semiconductor device is provided. The semiconductor device comprises a gate structure formed on a substrate, lightly doped drains formed in the substrate respectively at two sides of the gate structure, a spacer formed at sidewalls of the gate structure, and a source/drain having a recess filled with a top amorphous layer formed in the substrate respectively at two sides of the gate structure. A top surface of the top amorphous layer is substantially even with a surface of the substrate.

According to the present invention, PAI is replaced with the deposition process for forming the top amorphous layer/barrier layer. Thus TED effect is eliminated while SCE is still reduced by the top amorphous layer/barrier layer formed by the deposition process. Furthermore, the narrow line width effect is reduced by the top amorphous layer, which serves as the barrier layer. Therefore application of Pt in salicide process is eliminated, and thus waste of process time and cost for removing un-reacted Pt-containing metal layer is prevented by the provided method.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 are schematic drawings illustrating a first preferred embodiment of the method for manufacturing a semiconductor device.

FIGS. 6-10 are schematic drawings illustrating a second preferred embodiment of the method for manufacturing a semiconductor device.

### DETAILED DESCRIPTION

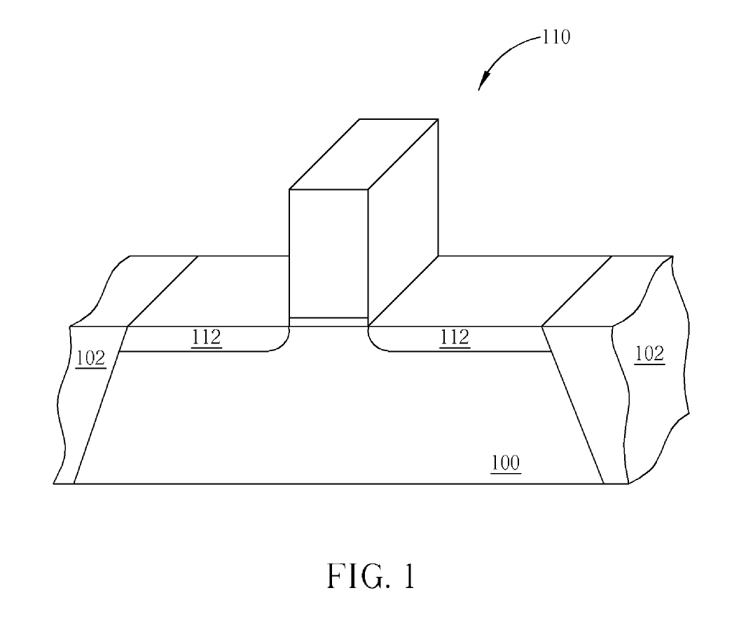

Please refer to FIGS. 1-5, which are schematic drawings illustrating a first preferred embodiment of the method for manufacturing a semiconductor device provided by the present invention. As shown in FIG. 1, a substrate 100 having at least a gate structure 110 formed thereon is provided firstly. The substrate 100 also comprises shallow trench isolations (STIs) 102 used to provide electrical isolations between devices. Then, as shown in FIG. 1, lightly doped drains (LDDs) 112 are formed in the substrate 100 respectively at two sides of the gate structure 110.

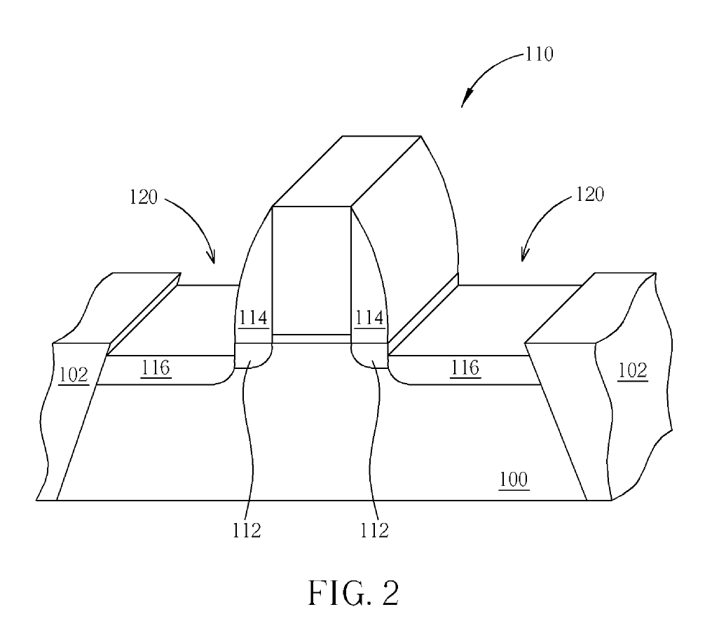

Please refer to FIG. 2. Next, a spacer 114 is formed at sidewalls of the gate structure 110 and followed by forming a source/drain 116 in the substrate 100 at two sides of the gate structure 110. After forming the source/drain 116, an etching process is performed to form recesses 120 respectively in the source/drain 116. In the first preferred embodiment, a depth of the recess 120 is substantially between 100 and 200 angstroms (A). Then a front-end-of-line (FEOL) clean process used to clean the recesses 120 is performed with standard clean 1 (SC1), O₃, HF, etc.

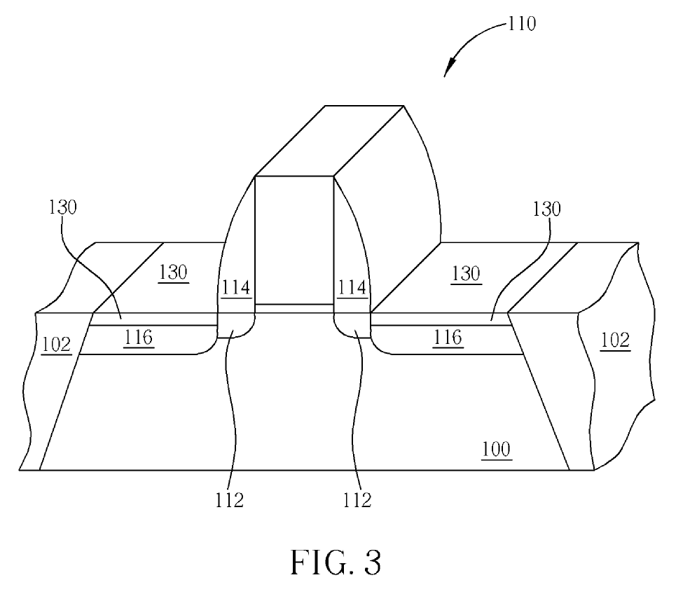

Please refer to FIG. 3. Next, a barrier layer 130 filling in the recess 120 is formed by performing a deposition process, such as atmospheric pressure chemical vapor deposition (APCVD) or reduced pressure chemical vapor deposition (RPCVD) but not limited thereto, and followed by a step of removing unnecessary barrier layer formed on places other than the recesses 120. It is noteworthy that by controlling process condition of the deposition process, such as at temperature of 500-900° C., vacuum of 3-50 torr, and with carrier gas such as H₂ in 10-50 standard-state cubic centimeter minute (sccm), dichlorosilane (DCS) in 10-300 sccm, GeH₄ in 10-300 sccm, and In(OH)₃ in 10-300 sccm, the barrier layer 130 is formed as an amorphous layer comprising SiOIn. Furthermore, since the barrier layer 130 fills in the recesses 120, top surfaces of the barrier layer 130 are substantially even with a surface of the substrate 100, as shown in FIG. 3.

It is well known that ions of different conductive types are used to form the LDDs 112 and the source/drain 116 depending on devices of different conductive types. For example, Arsenic (As) or Phosphorus is used for LDDs or source/drain of N-type device while Boron (B) or BF₂ are used for LDDs or source/drain of P-type device. Sometimes opposite ions are introduced for serving as halos. For example, Indium (In) is used for N-type device halos while As or P is used for P-type halos. However, no matter which conductive type the device is, the barrier layer 130 provided by the present invention is formed as an In-containing amorphous layer.

Thus, a semiconductor device is provided according to the first preferred embodiment. The semiconductor device comprises the gate structure 110 formed on the substrate 100, LDDs 112 formed in the substrate 100 respectively at two sides of the gate structure 110, the spacer 114 formed at the sidewalls of the gate structure 110, and the source/drain 116 having the recess 120 filled with a top amorphous layer serving as the barrier layer 130 formed in the substrate 100 respectively at two sides of the gate structure 110. The top surface of the top amorphous layer/barrier layer 130 is substantially even with the surface of the substrate 100. A depth of the recess 120 is substantially between 100 and 200 angstroms. And it is noteworthy that the top amorphous layer 130 filling in the recess 120 comprises SiOIn.

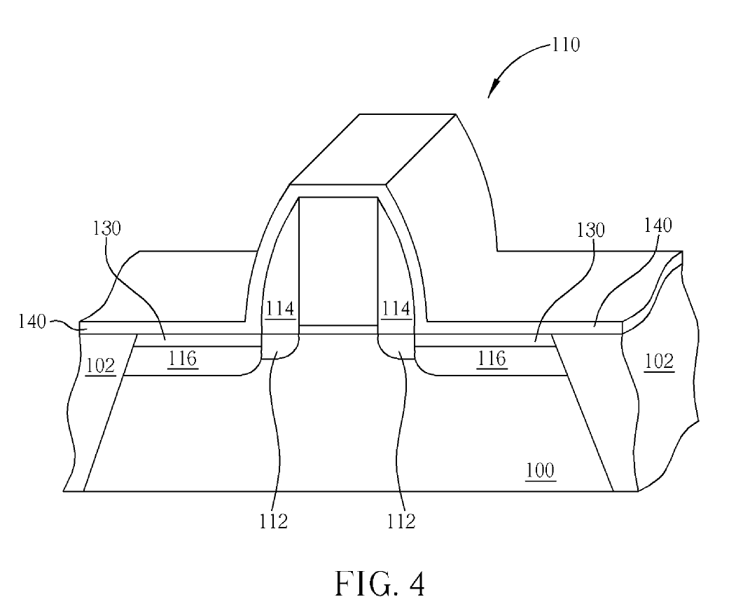

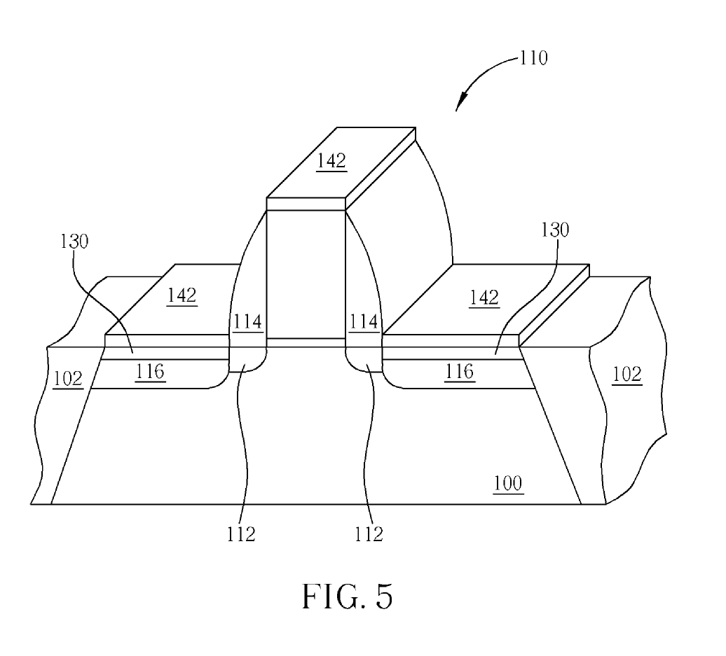

Please refer to FIGS. 4-5. Then, a self-alignment silicide (salicide) process is performed. The Salicide process includes steps of forming a metal layer 140 such as a Nickel (Ni), cobalt (Co), titanium (Ti) or molybdenum (Mo), on the substrate 100 as shown in FIG. 4 and sequentially performing a first rapid thermal process (RTP), a wet etching process for removing un-reacted metal layer, and a second RTP. Additionally, a titanium nitride (TiN) layer (not shown) can be formed on the metal layer 140 serving as a diffusion barrier. Thus salicide layers 142 are formed on the barrier layer 130 and on the gate structure 110 as shown in FIG. 5.

According to the method provided by the present invention, the deposition process replaces PAI that used to form the top amorphous layer/barrier layer 130. Therefore damage to the silicon lattice of the substrate 100, such as interstitial defects, created by implanting ions in PAI is avoided. In other words, PAI and its drawbacks such as TED effect are eliminated while the top amorphous layer 130, which is intentionally formed for reducing SCE, is still formed by the deposition process.

According to the method provided by the present invention, the manufactured semiconductor device possesses another advantage: It is well-known that platinum (Pt) is often added in the metal layer 140 for preventing agglomeration, which causes narrow line width effect, occurring in salicide layers 142. However, it is extremely difficult to remove the un-reacted Pt-containing metal layer. According to the present invention, the narrow line width effect is reduced by forming the top amorphous layer/barrier layer 130. Therefore application of Pt is eliminated, and thus waste of process time and cost for removing the un-reacted Pt-containing metal is prevented by the provided method.

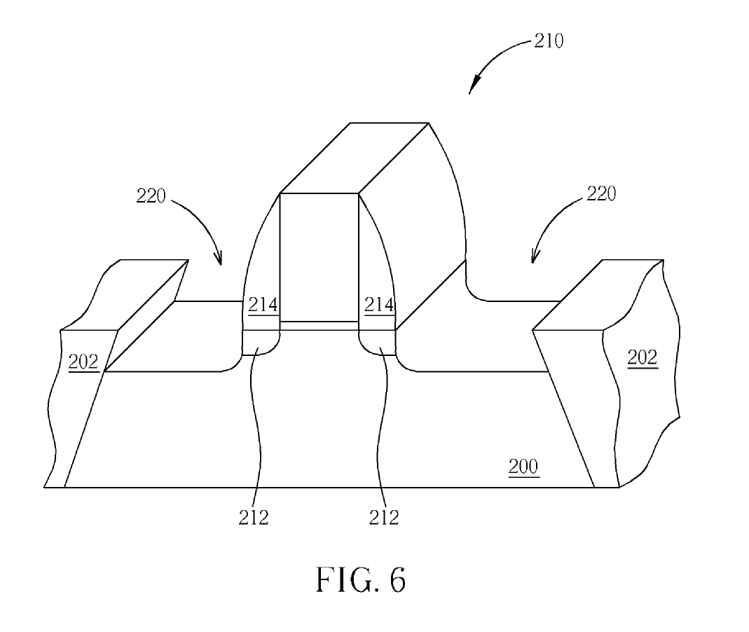

Please refer to FIGS. 6-10, which are schematic drawings illustrating a second preferred embodiment of the method for manufacturing a semiconductor device provided by the present invention. As shown in FIG. 6, a substrate 200 having at least a gate structure 210 formed thereon is provided firstly. The substrate 200 also comprises STIs 202 used to provide electrical isolations between the devices. Then, as shown in FIG. 6, LDDs 212 are formed in the substrate 200 respectively at two sides of the gate structure 210.

Please still refer to FIG. 6. Next, a spacer 214 is formed at sidewalls of the gate structure 210 and followed by performing an etching process for forming recesses 220 in the substrate 200 respectively at two sides of the gate structure 210. It is noteworthy that the recess 220 is formed in a predetermined source/drain region and a depth of the recess 220 is substantially between 500 and 1000 angstroms.

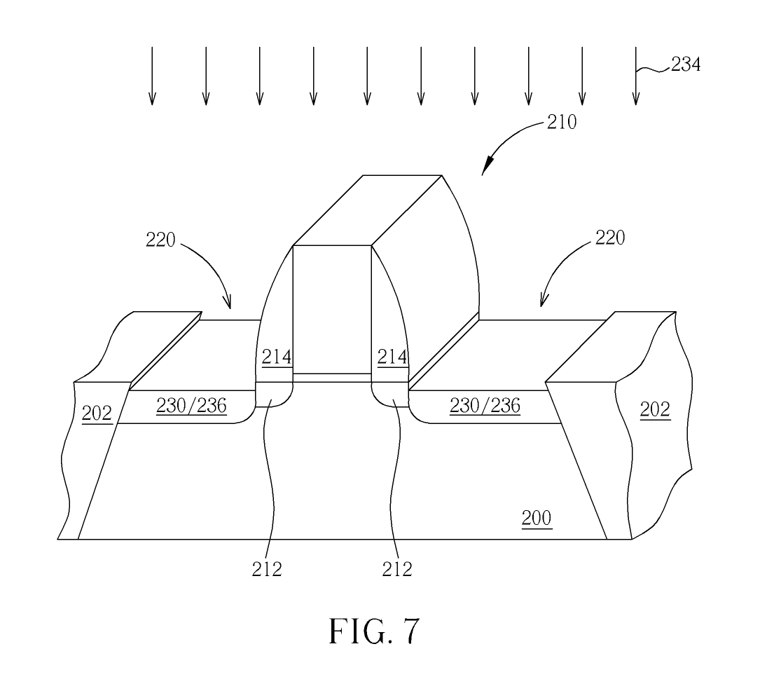

Please refer to FIG. 7. After the etching process, a selective epitaxial growth (SEG) process is performed to form an epitaxial layer 230 in the recess 220, respectively. The epitaxial layers 230 are formed along surface of the substrate 200 in each recess 220 to be a recessed source/drain of a MOS transistor. Those skilled in the art will easily realize that an ion implantation process can be performed before etching the recesses 220 or after performing SEG process to complete the formation of the recessed source/drain. The epitaxial layer 230 comprises silicon germanium (SiGe) or silicon carbide (SiC). When the gate structure 210 is a gate structure of a P-type device, the epitaxial layer 230 comprises SiGe; when the gate structure 210 is a gate structure of an N-type device, the epitaxial layer 230 comprises SiC.

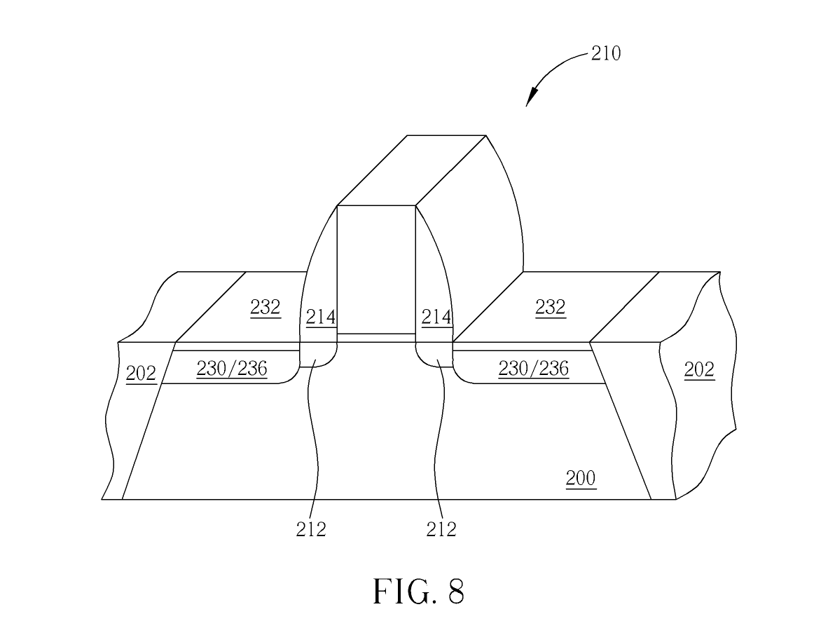

Please refer to FIG. 8. Next, a barrier layer 232 filling in the recess 220 is formed on the epitaxial layer 230 by performing a deposition process, such as APCVD or RPCVD. As mentioned above, by controlling process condition of the deposition process, such as at temperature of 500-900° C., vacuum of 3-50 torr, and with carrier gas such as H₂ in 10-50 sccm, DCS in 10-300 sccm, GeH₄ in 10-300 sccm, and In(OH)₃ in 10-300 sccm, the barrier layer 232 is formed as an amorphous layer comprising SiOIn. Furthermore, since the barrier layer 232 fills in the recesses 220, top surfaces of the barrier layer 232 are substantially even with the substrate 200, as shown in FIG. 8. As mentioned above, the barrier layer 232 provided by the present invention is formed as an In-containing amorphous layer regardless of conductive types of the devices.

It is noteworthy that the SEG process for forming the epitaxial layer 230 and the deposition process for forming the barrier layer 232 are performed in-situ.

In the second preferred embodiment the SEG methodology is introduced for further improving drain induced barrier lowering (DIBL) and punchthrough effect, and reducing off-state current leakage and power consumption while the process of semiconductor is approaching 45 nm.

Thus, a semiconductor device is provided according to the second preferred embodiment. The semiconductor device comprises the gate structure 210 formed on the substrate 200, LDDs 212 formed in the substrate 200 respectively at two sides of the gate structure 210, the spacer 214 formed at the sidewalls of the gate structure 210, a source/drain having a bottom non-amorphous layer 230 and a top amorphous layer 232 formed atop of the bottom non-amorphous layer 230 in the substrate 200 respectively at two sides of the gate structure 210. As mentioned above, the bottom non-amorphous layer 230 is an epitaxial layer formed by SEG process and it comprises SiGe or SiC depending on conductive types of the devices. The top amorphous layer 232 comprising SiOIn serves as barrier layer. It is noteworthy that the bottom non-amorphous layer 230 and the top amorphous layer 232 fill in the recess 220 having a depth of 500-1000 angstroms.

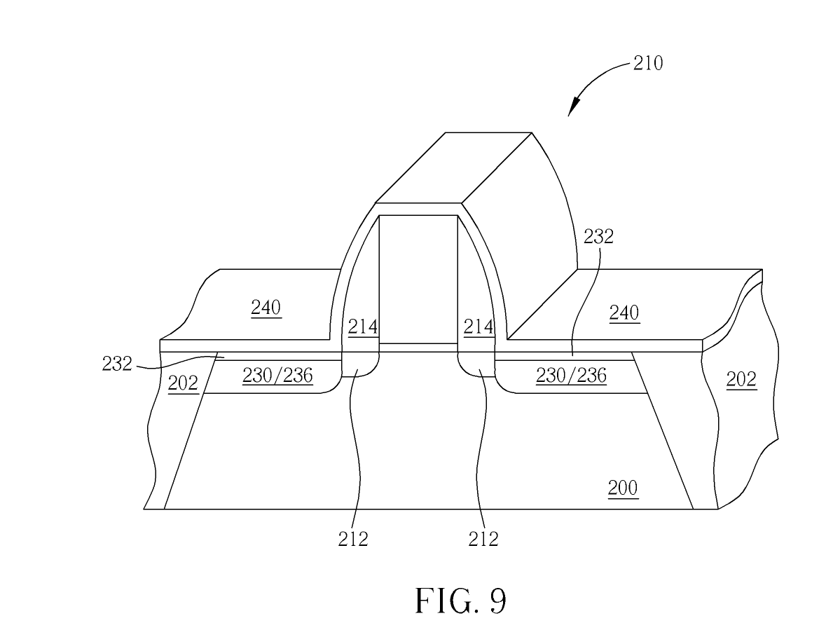

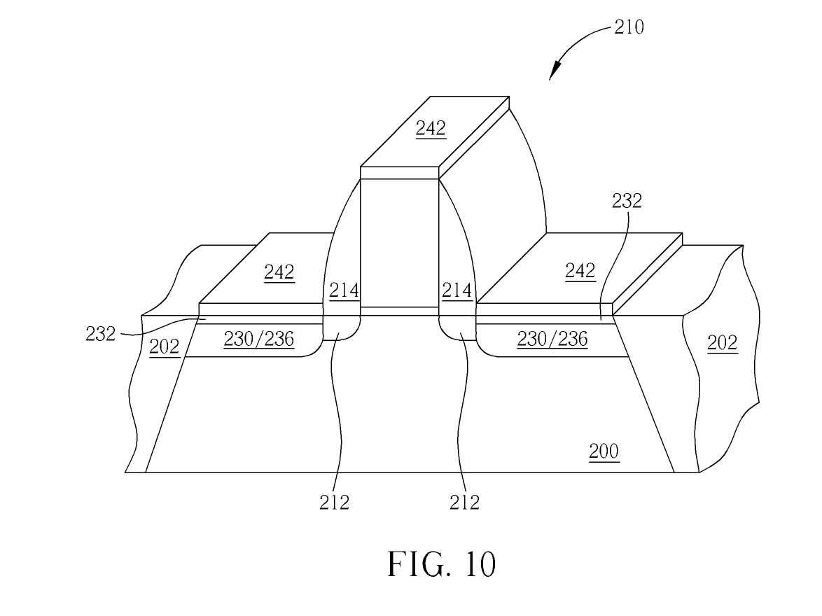

Please refer to FIGS. 9-10. Then, a salicide process is performed. As mentioned above, the Salicide process includes steps of forming a metal layer such as Co, Ti, Mo, or Ni layer 240 on the substrate 200 as shown in FIG. 9, and sequentially performing a first RPT, a wet etching process for removing un-reacted metal layer, and a second RTP. Additionally, a TiN layer (not shown) can be formed on the metal layer 140 serving as a diffusion barrier. Thus salicide layers 242 are formed on the barrier layer 232 and the gate structure 210 as shown in FIG. 10.

According to the second preferred embodiment provided by the present invention, PAI that used to form the top amorphous layer/barrier layer 232 is replaced by the deposition process. Therefore damage to the silicon lattice of the substrate 200, such as interstitial defects, created by implanting ions in PAI is avoided. In other words, PAI and its drawbacks such as TED effect are eliminated while the top amorphous layer/barrier layer 232, which is intentionally formed for reducing SCE, is still formed by the deposition process.

As mentioned above, according to the second preferred embodiment provided by the present invention, the narrow line width effect is reduced by the top amorphous layer/barrier layer 232. Therefore application of Pt in Salicide process is eliminated, and thus waste of process time and cost for removing the un-reacted Pt-containing metal is prevented by the provided method.

In summary, according to the present invention, PAI used to form the top amorphous layer/barrier layer is replaced by the deposition process, thus TED effect is eliminated. And SCE is still reduced by the top amorphous layer/barrier layer formed by the deposition process. Furthermore, the narrow line width effect is reduced by the top amorphous layer 232 serving as the barrier layer. Therefore application of Pt in salicide process is eliminated, and thus waste of process time and cost is prevented by the provided method.

Those skilled in the art will readily observe that numerous modifications and alterations of the device and method may be made while retaining the teachings of the invention.

1. A method for manufacturing a semiconductor device comprising steps of:
providing a substrate having at least a gate structure formed thereon;
forming lightly doped drains (LDDs) in the substrate and a spacer at sidewalls of the gate structure;
forming a source/drain in the substrate;
performing an etching process to form recesses respectively in the source/drain;
performing a deposition process to form a barrier layer filling in the recesses; and
performing a self-alignment silicide (salicide) process.

2. The method of claim 1, wherein a depth of the recesses is substantially between 500 and 1000 angstroms.

3. The method of claim 2 further comprising a step of performing a selective epitaxial growth (SEG) process to form an epitaxial layer serving respectively in the recesses before the deposition process.

4. The method of claim 3, wherein the epitaxial layer comprises silicon germanium (SiGe) or silicon carbide (SiC).

5. The method of claim 3, wherein the deposition process and the SEG process are performed in-situ.

6. (canceled)

7. The method of claim 1, wherein the barrier layer comprises an amorphous layer.

8. The method of claim 7, wherein the barrier layer comprises an In-containing amorphous layer.

9-17. (canceled)
